(19) United States
(12) Patent Application Publication
(10) Pub. No.: US 2006/0285701 A1
(43) Pub. Date: Dec. 21, 2006

(54) System and method for OS control of application access to audio hardware

(76) Inventors: Robert Bryant Chumbley, Austin, TX (US); Merle Sterling, Austin, TX (US)

Correspondence Address: JANIS E. CLEMENTS, 3112 LOMITA DRIVE, AUSTIN, TX, 78738, US

(21) Appl. No.: 11/154,903

(22) Filed: Jun. 16, 2005

(51) Int. Cl. H03G 3/00

(52) U.S. Cl. 381/104

(57) ABSTRACT

A system and method for OS control of application access to audio hardware provides means for a user to specify in a control panel applications from which sounds will be played through audio hardware. Selections of applications are made, and modifications to the selections are stored as configuration data, including volume level, balance level, and other audio settings for each application selected. Applications request to output data. Audio device drivers installed in operating system adhere to application list request and only output sounds from applications enabled by the user. A user need not modify individual application settings or turn off system sounds to implement the present invention. One interface controls application access to sound hardware in the present invention.

### TECHNICAL FIELD

The present invention relates to controlling sound output in a computing device, and particularly to functions in the basic input/output system (BIOS) and OS that allow a user to display a list of installed applications from which to select, make modifications to selected applications, including data volume level for each application, and store selections and modifications as configuration data.

### BACKGROUND OF RELATED ART

In the current art relating to OS control of application access to audio hardware, computer applications produce audio, such as media players, web browsers, instant messengers, and the operating system. A user may have more than one audio producing application running at the same time, and as a result, may hear audio from several applications at the same time. For example, a user may receive a “ding” sound from an instant messenger client while watching a DVD or playing a CD and would rather not be disturbed with other sounds while running the media player application.

Operating systems provide a mixer for control of sounds and sound cards often provide their own mixer applet that either replaces or augments the system mixer. However, these mixer applets currently provide only controls for master volume and levels of specific inputs, such as CD, WAVE, line in, mic in, and the like. The current art provides no control over which applications can use the sound hardware. Unless an application opens an audio device in an exclusive mode, any application can send sound data to the audio device and in systems such as Windows XP™, the operating system will handle mixing all sound streams together and sending them to sound hardware, resulting in the user hearing all the sounds together. To limit the sound output to a single application, a user must manually use the control panel applet to turn off system sounds and adjust the settings of each individual running application to turn off their sounds, assuming the application has such a setting. To re-enable sound outputs from the system and other applications, the user must again manually tweak the settings of the system control panel and each individual application. Alternatively, the user can close all running applications other than the application the user wants to hear and restart the applications when the user wants to re-enable their sounds.

The current art of controlling sound output in a computing device is quite a tedious and time-consuming process for such a simple operation of limiting output of sound to a single application for a short period of time. As computers become the center of home entertainment, this problem will become greater. Products such as Microsoft's Windows XP Media Center Edition™ and Gateway's FMC-901 Family Room Media Center™ are making inroads into the home theatre environment and the trend will continue as computer and consumer electronics converge. A mechanism is needed that allows a user to quickly specify which application sounds are to be heard and have the operating system send only the designated streams to the audio hardware.

### SUMMARY OF THE PRESENT INVENTION

The present invention provides a method for controlling sound output in a computing device using an operating system (OS) and particularly to functions in the basic input/output system (BIOS) and OS that allow a user to specify from a list displayed by a control panel, which application sounds will be played through the audio hardware and which are to be ignored. Selections of one or more applications and modifications to selections are stored as configuration data, including volume level, balance level, and other audio settings for each selected application. The audio device drivers installed in the operating system will respect this application list request and output only sounds from applications that are enabled by the user. The user would not need to modify individual application settings or turn off system sounds. The user uses one interface that controls application access to the sound hardware.

### BRIEF DESCRIPTION OF THE DRAWINGS

The present invention will be better understood and its numerous objects and advantages will become more apparent to those skilled in the art by reference to the following drawings, in conjunction with the accompanying specification, in which:

FIG. 1 is a block diagram of a generalized multiprocessor system on which the present invention for controlling sound output in a computing device may be practiced;

FIG. 2 is a diagrammatic illustration of a control panel of the present invention;

FIG. 3 is an illustrative flowchart describing the setting up of the functions for controlling sound output in a computing device of the present invention;

FIG. 4 is a flowchart of an illustrative run of the program set up according to FIG. 3; and

FIG. 5 is a flowchart of an illustrative run of the program set up according to FIG. 3.

### DETAILED DESCRIPTION OF THE PREFERRED EMBODIMENT

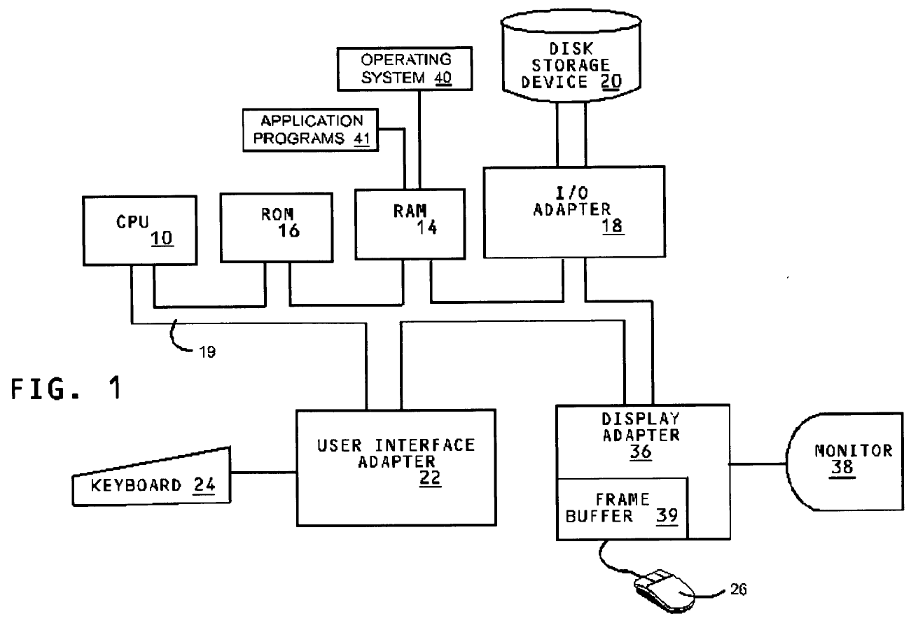

Referring to FIG. 1, a generalized system is shown which may function as a basic data processing system on which the present invention may be implemented. A CPU 10 is provided and interconnected to various other components by system bus 19. An operating system 40 runs on a CPU 10, provides control and is used to coordinate the functions of the various components of FIG. 1. Operating system 40 may be one of the commercially available operating systems which is capable of handling multiprocessing, such as IBM's AIX 6000™ operating system or the OS/2™ operating system available from IBM, Microsoft's Windows NT™, as well as other UNIX and AIX operating systems. The operating system is in random access memory (RAM) 14 during the system operations. Application programs 41 controlled by the system are moved into and out of the main memory, RAM 14.

The system shown in FIG. 1 also includes the following conventional elements. A read only memory (ROM) 16 is connected to CPU 10 via system bus 19 and includes the basic input/output system (BIOS) that controls the basic computer functions. RAM 14 and I/O adapter 18 are also interconnected to system bus 19. I/O adapter 18 may be a small computer system interface (SCSI) adapter that communicates with the disk storage device 20. I/O devices are also connected to system bus 19 via user interface adapter 22 and display adapter 36. Keyboard 24 and mouse 26 are all interconnected to bus 19 through user interface adapter 22. It is through such input devices that the user may interactively relate to the browser and the related programs according to the present invention. Display adapter 36 includes a frame buffer 39, which is a storage device that holds a representation of each pixel on the display screen of the monitor 38. Images may be stored in frame buffer 39 for display on monitor 38 through various components, such as a digital to analog converter (not shown) and the like. By using the aforementioned I/O devices, a user is capable of inputting information to the system through the keyboard 24 or mouse 26 and receiving output information from the system via display 38.

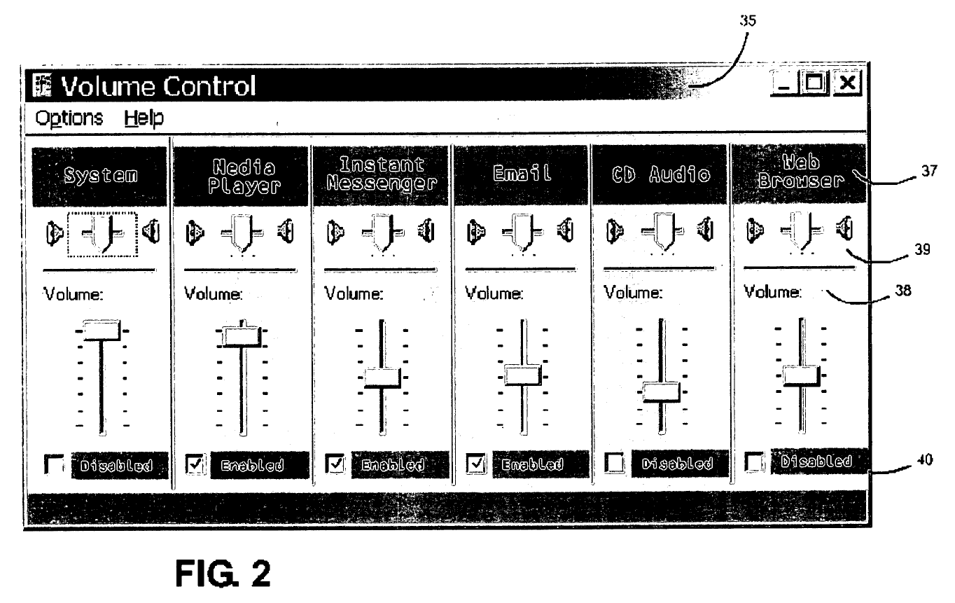

In FIG. 2 there is illustrated a control panel 35 of a computing device wherein a list of applications 37 is shown. A user selects from the list of application 37 each application from which the user wants to hear sound for a determined period of time. The user may also designate a volume level 38, balance 39, and other audio settings for each application. Also shown is an indication 40 of whether audio settings are enabled or disabled.

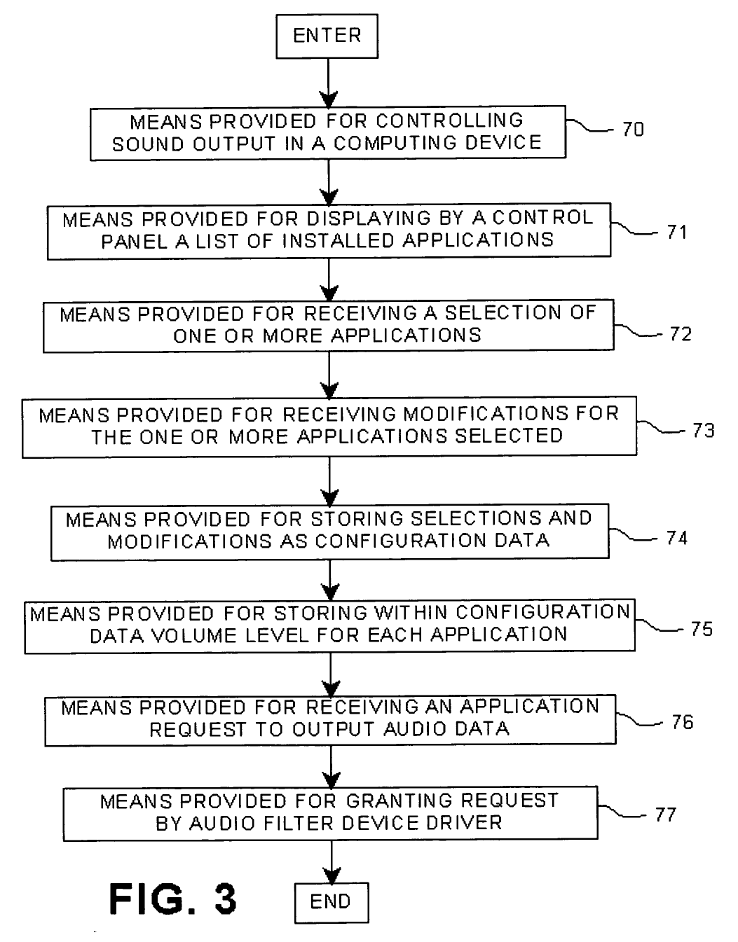

FIG. 3 is a flowchart showing the development of a process according to the present invention for controlling sound output in a computing device. Means are provided for controlling sound output in a computing device, step 70. Means are provided for displaying by a control panel a list of installed applications, step 71. The control panel can control sound output via a system mixer. A separate application can be added to the control panel for controlling sound output. A separate application in a system tray can be started at boot time for controlling sound output. Means are provided for receiving a selection of one or more applications, step 72. Means are provided for receiving modifications for the one or more applications selected, step 73. Means are provided for storing selections and modifications as configuration data, step 74. Means are provided for storing within configuration data volume level and other audio settings for each application, step 75. Means are provided for receiving an application request to output audio data, step 76. Means are provided for granting request by audio filter device driver, step 77. Further, a detection of whether the source of audio is enabled by a filter driver, and passing data to detected audio hardware, can be included in the present invention. An audio device driver base can be modified to control sound output. Drivers can be enabled to control sound output by audio hardware vendors.

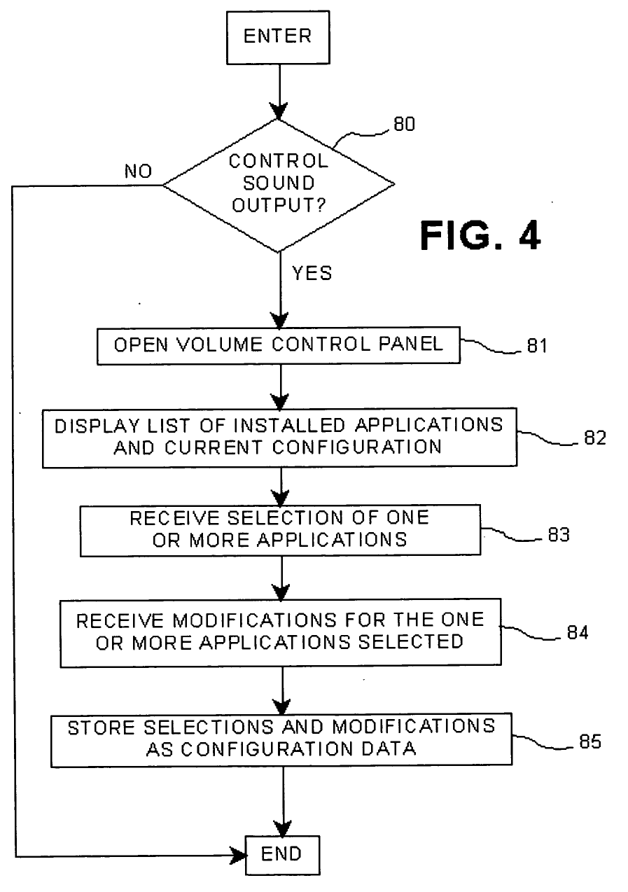

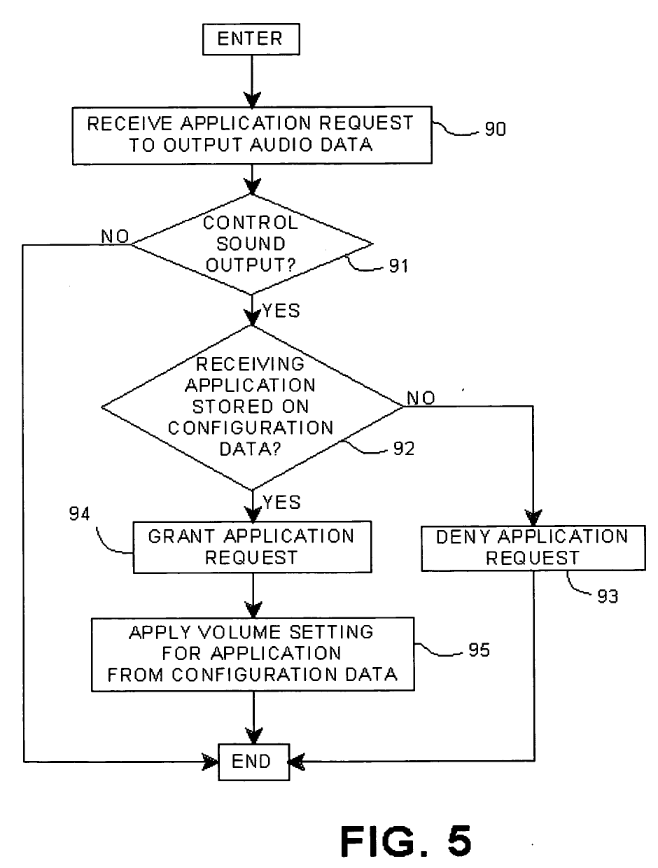

A simplified run of the process set up in FIG. 3 will now be described with respect to the flowchart of FIGS. 4 and 5. In FIG. 4, the process of selecting applications and making modifications thereto is described, while FIG. 5 describes the implementation process of using configuration data containing the application selections and modifications to selected applications. In FIG. 4, a determination is made regarding whether to control sound output on a computing device, step 80. If No, the process ends. If Yes, the control panel is opened, step 81, which displays a list of installed applications and their current configuration, step 82. Selection of one or more applications is received from user, step 83. Modifications for the one or more applications selected are received from user, step 84. Selections and modifications are stored as configuration data, step 85. Then the process of setting up audio settings and configurations for controlling sound output ends.

A simplified run of the process set up in FIG. 3 will now be described with respect to the flowchart of FIG. 5. First, an application request to output audio data is received, step 90. Then a determination is made regarding whether to control sound output, step 91. If No, the process ends. If Yes, then a determination is made regarding whether requesting application is stored in configuration data, step 92. If No, the application request is denied, step 93, and the process ends. If Yes, the application request is granted, step 94, then volume setting for application from configuration data is applied, step 95, and the process ends.

One of the preferred implementations of the present invention is an application program 41 made up of programming steps or instructions resident in RAM 14, FIG. 1, during computer operations. Until required by the computer system, the program instructions may be stored in another readable medium, e.g. disk drive 20, or in a removable memory such as an optical disk for use in a CD ROM computer input or in a floppy disk for use in a floppy disk drive computer input. One skilled in the art should appreciate that the processes controlling the present invention are capable of being distributed in the form of computer readable media of a variety of forms.

Although certain preferred embodiments have been shown and described, it will be understood that many changes and modifications may be made therein without departing from the scope and intent of the appended claims.

1. A method for controlling sound output in a computing device, comprising:
displaying by a control panel a list of installed applications;
receiving a selection of one or more applications;
receiving at least one modification for the one or more applications selected;
storing the selections and modifications as configuration data;
storing volume level for each application in the configuration data;
receiving an application request to output audio data; and
granting the application request regarding application stored in the configuration data by an audio filter device driver.

2. The method of claim 1 wherein the control panel controls sound output via a system mixer.

3. The method of claim 1 wherein a separate application is added to the control panel for controlling sound output.

4. The method of claim 1 wherein a separate application in a system tray is started at boot time for controlling sound output.

5. The method of claim 1 further comprising:
detecting whether source of audio is enabled by a filter driver; and
passing data to detected audio hardware.

6. The method of claim 5 wherein an audio device driver base is modified to control sound output.

7. The method of claim 5 wherein drivers are enabled to control sound output by audio hardware vendors.

8. A computer operating system for controlling sound output in a computing device, comprising:
means for displaying by a control panel a list of installed applications;
means for receiving a selection of one or more applications;
means for receiving at least one modification for the one or more applications selected;
means for storing the selections and modifications as configuration data;
means for storing volume level for each application in the configuration data;
means for receiving an application request to output audio data; and
means for granting the application request regarding application stored in the configuration data by an audio filter device driver.

9. The system of claim 8 wherein the control panel controls sound output via a system mixer.

10. The system of claim 8 wherein a separate application is added to the control panel for controlling sound output.

11. The system of claim 8 wherein a separate application in a system tray is started at boot time for controlling sound output.

12. The system of claim 8 further comprising:
means for detecting whether source of audio is enabled by a filter driver; and
means for passing data to detected audio hardware.

13. The system of claim 12 wherein an audio device driver base is modified to control sound output.

14. The system of claim 12 wherein drivers are enabled to control sound output by audio hardware vendors.

15. A computer program having code recorded on a computer readable medium for controlling sound output in a computing device, comprising:
displaying by a control panel a list of installed applications;
receiving a selection of one or more applications;
receiving at least one modification for the one or more applications selected;
storing the selections and modifications as configuration data; storing volume level for each application in the configuration data;
receiving an application request to output audio data; and
granting the application request regarding application stored in the configuration data by an audio filter device driver.

16. The computer program of claim 15 wherein the control panel controls sound output via a system mixer.

17. The computer program of claim 15 wherein a separate application is added to the control panel for controlling sound output.

18. The computer program of claim 15 wherein a separate application in a system tray is started at boot time for controlling sound output.

19. The computer program of claim 15 further comprising:
detecting whether source of audio is enabled by a filter driver; and
passing data to detected audio hardware.

20. The computer program of claim 19 wherein an audio device driver base is modified to control sound output.
